(19) United States
(12) Patent Application Publication
(10) Pub. No.: US 2005/0104507 A1
(43) Pub. Date: May 19, 2005

(54) Scanning display

(75) Inventors: Johannes Nicolaas Huiberts, Eindhoven (NL); Adrianus Sempel, Eindhoven (NL); Pieter Jacob Snijder, Eindhoven (NL); Henricus Franciscus Johannus Jacobus Van Tongeren, Eindhoven (NL); Coen Theodorus Hubertus Fransiscus Liedenbaum, Eindhoven (NL); Gerjan Franciscus Arthur Van De Walle, Eindhoven (NL)

Correspondence Address: Corporate Patent Counsel;Philips Electronics North America Corporation, P O Box 3001, Briarcliff Manor, NY, 10150, US

(73) Assignee: Koninklijle Philips Electronics N.V.

(21) Appl. No.: 10/501,417

(22) PCT Filed: Dec. 23, 2002
(86) PCT No.: PCT/IB02/05717

(30) Foreign Application Priority Data
Jan. 17, 2002 (EP) 02075200.2

(51) Int. Cl. H01J 1/62; H01J 63/04

(52) U.S. Cl. 313/500

(57) ABSTRACT

This invention relates to a display device (5) comprising first and a second sub-pixel (5a, 5b), said first sub-pixel (5a) emitting light of a first wavelength (λ1) and said second sub-pixel (5b) emitting light of a second wavelength (λ2), said first sub-pixel (5a) comprising a first organic electroluminescent layer (1a), such as a polymer or a small-compound molecule layer, which is sandwiched between a front and a back electrode (2a, 3a), with a first state in which an emission driving signal (Vₐₗ) is applied across said first layer (1a) for generating an emission state in which light of said first wavelength (λ1) is emitted, and with a second state in which a sensing driving signal (Vₐₛ) is applied across said first layer (1a), whereby light of said second wavelength (λ2) incident on said first sub-pixel (5a) can be detected. Preferably, said first electrodes (2a, 3a) are held at essentially the same potential.

This invention relates to a display device comprising at least a first sub-pixel comprising a first light-emitting organic electroluminescent layer, such as a polymer layer or a small-compound molecule layer, which is sandwiched between a first front electrode (anode) and a first back electrode (cathode).

Organic electroluminescent displays and devices are fairly recently discovered technologies that are based on the realization that certain organic materials such as, for example, polymers of the class of the polyphenylene vinylenes and organic electroluminescent materials may be used as semiconductors in light-emitting diodes. These devices are very interesting due to the fact that the use of organic materials, such as polymer materials, make these devices light, flexible, and comparatively inexpensive to produce.

Recently it was also discovered that such light-emitting devices may be used as tools to measure incident light. Such a device has, for example, been described in the patent document U.S. Pat. No. 5,504,323. This document describes a light-emitting diode, which has a dual function and may thus be used in display technology for both input and output. When the organic polymer layer of the diode is positively biased the diode functions as a light emitter, and when the layer is negatively biased it functions as a photodiode. The negative bias preferably has a negative voltage being in the interval of 2.5 to 15 V. It is also described that, since the photosensitivity of the layer increases with the reversed voltage, it is preferred to have a quite large negative bias voltage across the organic polymer layer in the photodiode mode.

However, the dual-function diode, as described above, has a number of drawbacks. To start with, the device as described in U.S. Pat. No. 5,504,323 shows a non-symmetric leakage current behavior around 0 V, and the leakage currents are therefore found to be unstable. Moreover, the application of a high negative voltage leads to an increase of the failure probability of the device, and the dark current is highly unstable as it is directly related to defects/short circuits through the organic electroluminescent layer. This leads to a poor signal-to-noise ratio for photocurrent detection under reverse operation. Most importantly, however, the devices according to the prior art consume much power owing to the large driving voltages.

Moreover, a problem with such prior art displays is that it is hard to find a suitable light-emitting and sensing material, which is optimal for emitting as well as sensing for a specific wavelength or wavelength interval. Such functions are desired in devices such as scanners or interactive displays, in which light emitted from the display is reflected and is to be detected by the same display. An alternative device combining light-emitting and light-sensing abilities is therefore desired.

This and other objects are achieved by a display device as described by way of introduction, further comprising a second sub-pixel, wherein said first sub-pixel is arranged to emit light of a first wavelength and said second sub-pixel is arranged to emit light of a second wavelength, wherein said first front and back electrodes in a first state are arranged to apply an emission driving signal across said first electroluminescent layer for generating an emission state in which light of said first wavelength is emitted, and in a second state are arranged to apply a sensing driving signal across said first electroluminescent layer for generating a sensing state in which light of said second wavelength incident on said first sub-pixel may be detected. Preferably, said first electrodes (2a, 3a) are held at essentially equal potential, i.e. said sensing driving signal is a voltage having a value of essentially 0 Volts. Said second driving circuit is accordingly such that the power of said second driving signal has a zero value for accurately detecting an electric current generated in said organic electroluminescent layer when said organic electroluminescent layer is hit by external light. A display device is achieved thereby in which different sub-pixels for different colors are assigned different functions. As an example, an RGB device may be implemented, which uses reflected light originally emitted by high-energy sub-pixels (for example blue) while it senses with the low energy sub-pixels (for example red, green). Moreover, a display is obtained which may be switched between a light-emitting display mode and a scanning, sensing mode. Further examples will be given below. Furthermore, since the sensing is done at 0 volts, the power consumption is minimized, making the display useful for mobile applications. Moreover, the above eradicates the influence of leakage currents, which is a problem in prior art devices. Furthermore, an aspect of the invention is that it may be implemented in a “regular” RGB color display. In such a display, the wavelength difference between the colors is typically 100 nm (blue ˜440, green ˜540 nm, red ˜640 nm). The invention does not impose any further limitations on a choice of red, green, and blue compared with the limitations inherent in the three colors. As described above, light emitted from said second sub-pixel, having said second wavelength, is suitably arranged to be reflected and detected by said first sub-pixel during said light-sensing state, so that a scanning device or an interactive display device may be obtained. Moreover, light emitted from said first sub-pixel suitably has a lower energy content than light emitted from said second sub-pixel.

According to a preferred embodiment of this invention, the device further comprises a plurality of pixels, each comprising a first and a second sub-pixel, wherein light emitted from a chosen sub-pixel is arranged to be reflected by an external reflection device arranged in an area proximity of said display device and to be sensed by at least one first sub-pixel within said area. Such a device may be used as an interactive display, in which an external reflection device, such as a mirror pen, may be placed close to the display surface in order to reflect light within a certain, limited area. The reflected light is then sensed by the sensing sub-pixel(s) in question, whereby the position of the mirror pen on the display may be detected in that it is detected which sub-pixels sense the reflected light. Preferably, said display comprises a plurality of pixels, while light emitted from a second sub-pixel is arranged to be detected by a plurality of neighboring pixels, each having a corresponding first sub-pixel. The spatial resolution of the scanning display device may be improved thereby.

Preferably, said first front and back electrodes (the anode and cathode) each have a work function, and the difference between said work functions in greater than 1 eV, preferably within an interval of 2 to 3.5 eV. A comparably great difference between said work functions renders it possible to achieve a good sensing in the sensing state as well as an optimum emission in the emission state of the display. Moreover, said emission driving signal during the first emission state and said sensing driving signal during the second sensing state are preferably constituted by pulsed driving signals, the duration of the pulses being within an interval of 0 to 20 ms, thereby making it possible to integrate the device into a “regular” display device without the difference being noticeable to the human eye. According to a preferred embodiment of this invention, said sensing driving signal, in said second state, is a pulsed driving signal comprising high-intensity pulses, for amplifying the sensing driving signal. This pulsed scanning may greatly enhance the scanning, compared with continuous scanning. It can be demonstrated that by scanning in a pulsed mode with high intensity pulses, the sensing signal may improve by two orders of magnitude or more. Moreover, the pulsed driving prevents excessive heating of the materials, which could deteriorate or even destroy the device.

For reason of clarity, the EL device comprises one or more functional layers. Examples of such functional layers are an electroluminescent, charge transport and charge injecting layers. In order to fully exploit the benefits of the invention, the one or more functional layers are preferably provided using a wet deposition method

The one or, if there is more than one, at least one of the functional layers is an electroluminescent layer. The EL layer is made of a substantially, preferably organic, electroluminescent material. In the context of the invention, the type of EL material used is not critical and any EL material known in the art can be used. Preferably, however obtainable from a fluid which can be deposited using a wet deposition method. Suitable organic EL materials include organic photo- or electroluminescent, fluorescent and phosphorescent compounds of low or high molecular weight. Suitable low molecular weight compounds are well known in the art and include tris-8-aluminium quinolinol complex and coumarins. Such compounds can be applied using vacuum-deposition method. Alternatively, the low molecular weight compounds can be embedded in a polymer matrix or chemically bonded to polymers, for example by inclusion in the main chain or as side-chains, an example being polyvinylcarbazole.

Preferred high molecular weight materials contain EL polymers having a substantially conjugated backbone (main chain), such as polythiophenes, polyphenylenes, polythiophenevinylenes, or, more preferably, poly-p-phenylenevinylenes. Particularly preferred are (blue-emitting) poly(alkyl)fluorenes and poly-p-phenylenevinylenes which emit red, yellow or green light and are 2-, or 2,5-substituted poly-p-phenylenevinylenes, in particular those having solubility-improving side groups at the 2- and/or 2,5 position such as C₁-C₂₀, preferably C₄-C₁₀, alkyl or alkoxy groups. Preferred side groups are methyl, methoxy, 3,7-dimethyloctyloxy, and 2-methylpropoxy. More particularly preferred are polymers including a 2-aryl-1,4-phenylenevinylene repeating unit, the aryl group being optionally substituted with alkyl and/or alkoxy groups of the type above, in particular methyl, methoxy, 3,7-dimethyloctyloxy, or, better still, 2-methylpropoxy. The organic material may contain one or more of such compounds. Such EL polymers can suitably be applied by wet deposition techniques.

In the context of the invention, the term organic includes polymeric whereas the term polymer and affixes derived therefrom, includes homopolymer, copolymer, terpolymer and higher homologues as well as oligomer.

Optionally, the organic EL material contains further substances, organic or inorganic in nature, which may be homogeneously distributed on a molecular scale or present in the form of a particle distribution. In particular, compounds improving the charge-injecting and/or charge-transport capability of electrons and/or holes, compounds to improve and/or modify the intensity or color of the light emitted, stabilizers, and the like may be present.

The organic EL layer preferably has an average thickness of 50 nm to 200 nm, in particular, 60 nm to 150 nm or, preferably, 70 nm to 100 nm.

Optionally, the EL device comprises further, preferably organic, functional layers disposed between the electrodes. Such further layers may be hole-injecting and/or transport (HTL) layers and electron-injecting and transport (ETL) layers. Examples of EL devices comprising more than one functional layer are a laminate of anode/HTL layer/EL layer/cathode, anode/EL layer/ETL layer/cathode, or anode/HTL layer/EL layer/ETL layer/cathode.

Suitable materials for the hole-injecting and/or hole-transport layers (HTL) include aromatic tertiary amines, in particular diamines or higher homologues, polyvinylcarbazole, quinacridone, porphyrins, phthalocyanines, poly-aniline and poly-3,4-ethylenedioxythiophene.

Suitable materials for the electron-injecting and/or electron-transport layers (ETL) are oxadiazole-based compounds and aluminiumquinoline compounds.

If ITO is used as the anode, the EL device preferably comprises a 50 to 300 nm thick layer of the hole-injecting/-transport layer material poly-3,4-ethylenedioxythiophene or a 50 to 200 nm thick layer of polyaniline.

The invention will be described in closer detail below with reference to the accompanying drawings.

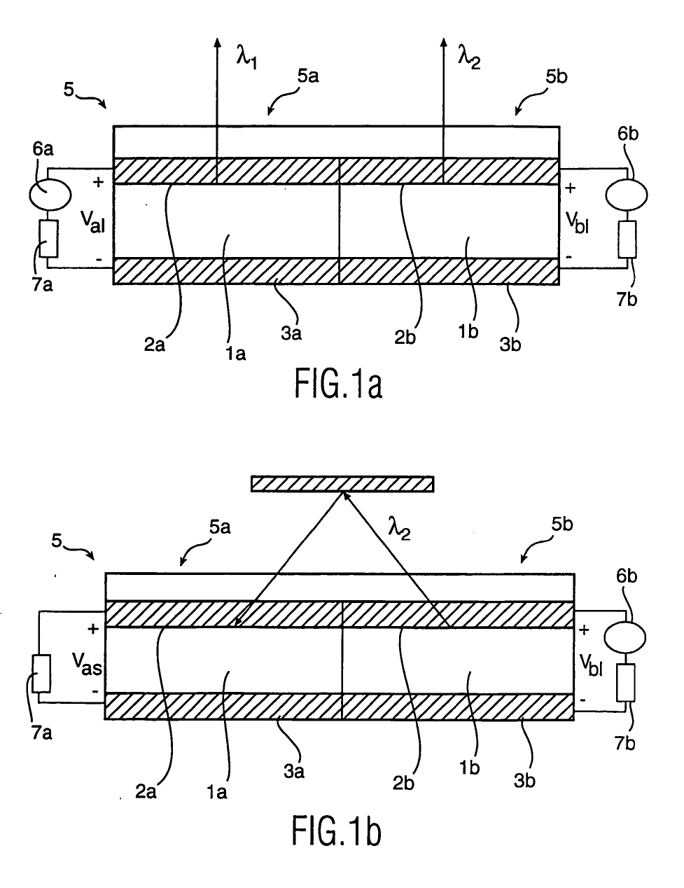

FIG. 1a is a schematic drawing of a dual-function display device having a first and a second sub-pixel, the display being in a light-emitting state.

FIG. 1b is a schematic drawing of the dual-function display device of FIG. 1a, one sub-pixel being in a light-emitting state, and one sub-pixel being in a light-sensing state, i.e. the display being in a so-called light-sensing or scanning state.

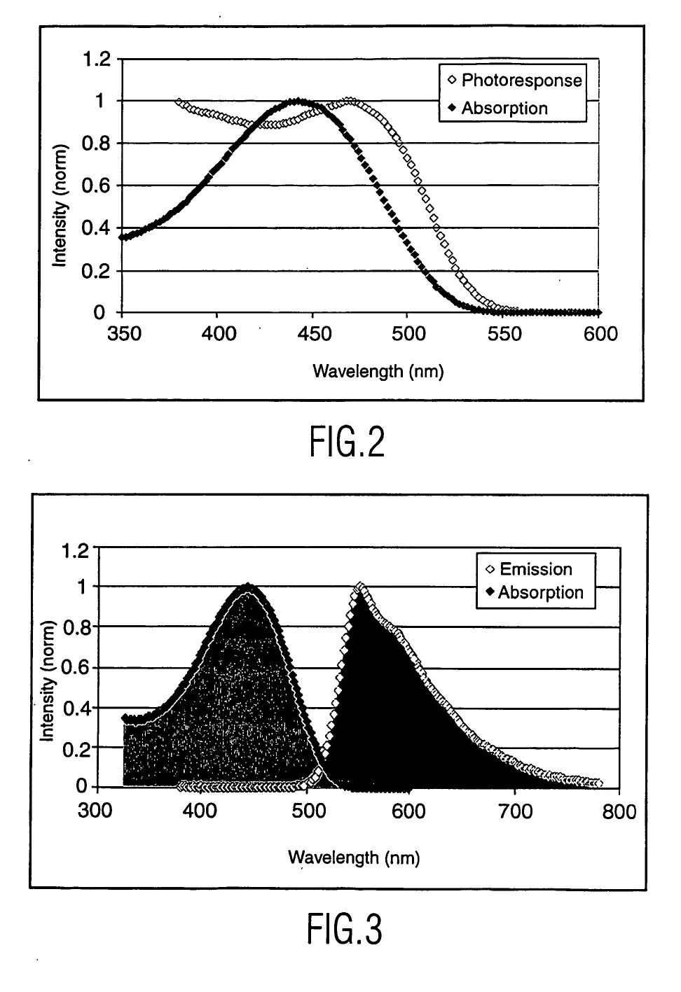

FIG. 2 is a diagram showing the normalized intensity of the absorption spectrum for a first example of a sub-pixel structure and the normalized photoconductivity spectrum for a second example of a sub-pixel structure display device under short-circuit circumstances.

FIG. 3 is a diagram showing the absorption spectrum for a first example of a sub-pixel structure and the emission spectrum for a second example of a sub-pixel structure display device under short-circuit circumstances.

A display device in accordance with the invention is schematically shown in FIG. 1a and FIG. 1b. The shown display 5 comprises a single pixel, with a first and a second sub-pixel 5a, 5b. It is to be noted, however, that a display incorporating the present invention may comprise a plurality of pixels, each comprising two or more sub-pixels, as will be described below. The display is arranged to be driven in two temporally separated modes, namely a first or emission mode, in which light is emitted from all sub-pixels (FIG. 1a), and a second or sensing mode, in which the second sub-pixel is arranged to emit light of a certain wavelength, while the first sub-pixel is arranged to sense incident light of the same wavelength (FIG. 1b), as will be described in more detail below.

The first sub-pixel 5a comprises a first active organic electroluminescent layer 1a, of, for example, an electroluminescent polymer material or a small-molecule material, which is sandwiched between a front and a back electrode 2a, 3a. The front electrode 2a functions as a so-called hole-injecting layer or anode, and the back electrode 3a functions as a so-called electron injecting layer or cathode. The material of said first electroluminescent layer is chosen such that a first wavelength λ1 is emitted in the first emission state or mode, when a first emission state voltage Vₐₗ is applied across said first electroluminescent layer 1a by means of a first power source 6a, connected to said electrodes 2a, 3a. Moreover, in this embodiment of the invention, the second sub-pixel 5b comprises a second light-emitting material layer 1b, such as an active organic electroluminescent layer as described above, which is also sandwiched between two electrodes, 2b, 3b. The second sub-pixel is arranged to emit light having said second wavelength λ2 when a second emission state voltage V_{bl} is applied across said first electroluminescent layer 1b by means of a second power source 6b, connected to said electrodes 2b, 3b. In the light emitting mode of the display shown in FIG. 1a, a voltage Vₐₗ is thus applied across the first sub-pixel 5a, and a voltage V_{bl} is applied across the second sub-pixel 5b.

Moreover, the fact that at least the first electroluminescent layer 1a is constituted by a electroluminescent polymer layer or a small-molecule material layer, implies that, when biased by a signal different from the driving signal Vₐₗ, i.e. a sensing voltage Vₐₛ, to be described below, light incident on the electroluminescent layer 1a will give rise to a photocurrent Iₚₕ through the layer material, which can be detected.

Furthermore, the material of said first electroluminescent layer 1a of the first sub-pixel 5a is such that incident light of a second wavelength λ2, emitted by said second sub-pixel 5b induces a photocurrent Iₚₕ in said material when the sensing-state voltage Vₐₛ is applied across said electroluminescent layer 1a. The photocurrent generated by the present invention may be measured, for example, by measuring the voltage drop across a measuring circuit 7a which is connected between said first front and back electrodes 2a, 3a. Moreover, light having said first wavelength λ1 is arranged to have a lower energy content than light having said second wavelength λ2, i.e. λ1<λ2.

Furthermore, the display device 5 may or may not comprise a front substrate 4, having the functions of stabilizing the display device and separating the active display parts from a potential user.

As was described above, at least the first sub-pixel 5a of the inventive display device has a dual function and may be driven in two modes or states by switching the display between light-emitting operation, as shown in FIG. 1a, and scanning/sensing operation, as shown in FIG. 1b. Said switching may be done automatically by using a pulsed driving schedule, or by a command from a potential user of the device. It is also possible to implement a display that can only be driven in the scanning/sensing state as shown in FIG. 1b.

As described above, a second emission voltage V_{bl} is applied across the second electroluminescent layer 1b in a first, light-emitting state (FIG. 1a) by means of a power source 6b, whereby light having a second wavelength λ2 is emitted from said second organic electroluminescent layer 1b. Moreover, a first emission voltage Vₐₗ is applied across the organic electroluminescent layer 1a by means of a power source 6a, whereby light having a first wavelength λ1 is emitted from said organic electroluminescent layer 1a. The first and second electrodes 2a, 3b described above have different work functions. An optimum charge injection into the polymer layer may be achieved thereby in the emission state, because the work function is a measure for the energy required to remove an electron from the surface of the respective first and second electrodes 2a, 3a. The first electrode 2 (the hole-injecting layer) has a high work function (Φ₁) and is arranged to remove electrons from the valence states with high binding energy, leaving positive holes behind in these states. The second electrode 3a (the electron-injecting layer) has a low work function (Φ₂), and the electrons are loosely bound in the material. The second electrode 3a is arranged to inject negatively charged electrons in the conduction states of the material, where the electrons also have a low binding energy. Under forward driving (where the first electrode is positive and the second electrode is negative), the holes and electrons move towards each other, so that the electrons fill up the holes, and the increase in binding energy results in the release of a photon, i.e. light is emitted having said first wavelength λ1. When the device is driven in the light-emission state, a certain voltage, referred to as the built-in voltage of the device, needs to be applied before any current will start to flow through the device. After this built-in voltage V_{b-i} has been reached, the value of the current through the display device will increase rapidly. The value of said built-in voltage is proportional to the difference between the work functions of the first and second electrodes.

In a second, sensing state (FIG. 1b), the second emission voltage V_{bl} is still applied across the second electroluminescent layer 1b of the second sub-pixel 5b by means of the power source 6b, whereby light having the second wavelength λ2 is emitted from said second organic electroluminescent layer 1b. However, in this state a sensing driving voltage Vₐₛ is applied across the first organic electroluminescent layer 1a of the first sub-pixel 5b, said voltage being applied by the power source 6a or by means of a separate power source (not shown), and light incident on the first sub-pixel 5a having the wavelength λ2 will give rise to the generation of a photocurrent Iₚₕ in the first organic electroluminescent layer 1a. According to this invention, said sensing driving voltage Vₐₛ has a zero value (Vₐₛ=0V, short-circuit configuration), i.e. a zero voltage is applied across the first organic layer 1a. The use of a short-circuit configuration minimizes, the power consumption of the display, and the influence of leakage currents may be eradicated. In the short-circuit state, the two electrodes of the first sub-pixel, now having the same potential, are separated by the insulating organic electroluminescent layer 1a, for example a polymer layer. However, in said layer there are always small leakage paths through which a small amount of charge is allowed to flow, provided there is a driving force. Due to the above-described difference in work function between the first and the second electrode, electrons in the layer 1a experience a high binding energy of the first electrode 2a and a low binding energy of the second electrode 3a. Thus electrons will move from the second to the first electrode, and a small transient current Iₜᵣ (present during a short time only) will flow until an equilibrium is reached. Initially, both electrodes where neutral, but due to said transient current the first electrode becomes negatively charged and the second electrode becomes positively charged, resulting in a negative field across the organic layer 1a. As was indicated above, the zero applied voltage has advantages relating to the leakage current and to the low power consumption necessary for the sensing state. At 0 V applied voltage, the electrodes 2a, 3a are set at the same voltage, and, the leakage currents are forced to 0 thereby because no external field is applied across the organic layer 1a. However, the above transient current gives rise to an negative internal electric field which is used to drive a photocurrent generated as external light hits the device in the sensing state. In the above case, the size of the internal field is given by:
Eᵢₙₜ=V_{b-i}/t_{layer}
where, Eᵢₙₜ is the internal field, V_{b-i} is the built-in voltage mentioned above, and t_{layer} is the thickness of the organic layer 1a. When illuminating the device, electrons being in an valence state are excited into a conduction state, and the negative internal electric field breaks the electron-hole pair and pulls the electron towards the second electrode 3a (the cathode) and the hole towards the first electrode 2a (the anode). Consequently, a small, measurable photocurrent is generated. Furthermore, since the built-in voltage V_{b-i} is proportional to the difference between the two work functions of the first and the second electrode, the internal electrical field is also proportional to the work function difference, i.e. the greater the difference between the two work functions, the stronger the internal electric field at 0 applied voltage. Moreover, a great work function difference is also required for an optimum emissive state, and a device is obtained thereby which may be optimized for emission, while still having an effective, power-efficient sensing state.

For present-day electrodes, the work function difference may be made large, resulting in high values of the built-in voltage V_{b-i} of between 1.4 and 3.1 Volts. Moreover, it was found that the optimum thickness of the organic layer 1a is in the interval between 60 and 90 nm and preferably about 70 nm, in order to achieve a high-efficiency emission state.

Consequently, this invention provides for a interactive/scanning display device by spectrally subdividing the sensor stage and the emission stage of the display. A reflecting object placed on or near the display surface is illuminated by (high-energy) emitting sub-pixels, whereas the reflected light is sensed under short-circuit conditions by (low-energy) sensing sub-pixels.

Specifically, the present invention makes it possible to include such scanning and/or interactive facilities in an organic color display, such as an RGB display. In such a display, each pixel comprises three sub-pixels arranged to emit light of mutually differing wavelengths, namely red light λ1, green light λ2, and blue light λ3. A color display requires the above three colors in order to map a major fraction of the so-called color triangle, and thus to be able to represent a major fraction of the colors present in the visible spectrum in a manner known per se. In an organic electroluminescent device however, using, for example, a polymer electroluminescent material, the energy differences between the different colors naturally more or less corresponds to the so-called Stokes shift (˜100-150 nm) of the polymer material. (The Stokes shift is equal to the energy difference between the absorption and the emission of the material). Consequently, the emission bands of the high-energy pixels essentially correspond to the absorption bands of the low-energy pixels of the color display, and a scanning display may thus be realized by starting from a standard electroluminescent display device.

A sensing state in such a device may be realized in several different ways:
1) using the blue sub-pixel for emitting light, and the red and/or green sub-pixel for sensing reflected light.
2) using the green sub-pixel for emitting light, and the red sub-pixel for sensing reflected light.
3) using the blue and green sub-pixels for emitting light, and the red sub-pixel for sensing reflected light.

It should be noted that the illumination is performed by sub-pixels emitting higher-energy photons, such as blue and/or green sub-pixels, and the sensing is performed by sub-pixels emitting lower-energy photons, such as green and/or red sub-pixels.

Furthermore, as indicated above, the organic electroluminescent materials, such as the active polymers in a polymer light-emitting device (poly-LED) have a very specific spectral absorption and emission behavior. The light absorption feature is situated at distinctly higher energies than the emission feature (typically 0.6 eV higher). For example, in PPV (polyphenylene vinylene) polymers, the spectral dependence of the photoconductivity coincides to a great extent with the absorption behavior, as is visible from FIG. 2. The moment the energy of an incoming photon is sufficient to create an exciton (bound electron-hole pair) charge carriers are thus generated by exciton break-up in the polymer layer.

Furthermore, as mentioned above, the wavelength difference between the absorption and the emission feature is typically 100 to 150 nm, as is visible from FIG. 3. FIG. 3 discloses the absorption and emission spectrum of a yellow PPV polymer, given as an example only. In FIG. 3, the absorption was measured for a 100 nm polymer layer on glass while the emission spectrum was measured for a 75 nm polymer layer in an ITO/PEDOT-PSS/Yellow PPV/BaAl device. The above wavelength difference is commonly attributed to the Stokes shift and is believed to be due to structural relaxation effects and a migration of excitons towards lower energy states during their lifetime (approximately 1 ns). This invention is based on the realization that the overlap between the emission and the absorption spectrum of the same polymer is too small to give an appreciable photo-response, and moreover, the above Stokes shift indicates the need for a spectral sub-division of the sensing and the emitting state in a scanning device or the like.

In accordance with the above, this invention further makes it possible to generate a full-color display (such as an RGB-display) having an incorporated scanning facility. Furthermore, it can be shown that the inventive short circuit configuration has a short response time. The response time is an especially important characteristic for interactive applications. The reason why the response time is of importance is that it is desirable to incorporate the sensor action in the multiplexed driving operation of the device. Simulations give that the response time for a display utilizing a short-circuit configuration is of the order of 10 μs, which is short enough to acquire a desired amplification of the signal.

Furthermore, the display device according to the invention is arranged to be driven by a pulsed driving signal. As was described below, a display in accordance with the invention may in practice be used in two different ways, namely as a scanning display arranged to display a picture for a viewer, the display continuing to display said picture in the sensing state, or as a pure scanning display, in which the emission is used to illuminate an object only and is not intended to hit the eye of a potential viewer.

In the first case, a pulsed driving schedule is suitable in order to avoid the incorporation of the sensing state to be noticed by a human eye. In this case, the duration of the pulses is of the order of 10 ms (within the interval of 0 to 20 ms).

In the second case, a pulsed driving schedule is beneficial for amplification purposes, the duration of the pulses being of the order of 10 ms (within the interval of 0 to 20 ms) at a sufficient amplification of the signal. Due to the short response time described above, it is possible to measure short, high signals, since the short pulses in this case enable the use of high-intensity light without excessive heating of the display, which may improve the sensing signal by at least a factor 2. Moreover, for a constant value of the total dissipated energy, the voltage across (or the current through) the electroluminescent layer may be increased when decreasing the pulse time, thus enabling an increase in the photocurrent signal. Such a pulsed driving schedule is highly suitable for polymer LEDs, especially in a passive matrix configuration. Moreover, the pulsed driving schedule increases the luminous intensity. As an example, for a multiplexed driving schedule with 15.6 ms driving pulses (64 cathodes), the luminous intensity in the pulse increases by a factor 64, since the power is proportional to the luminous intensity. Moreover, for an RGB display in a passive matrix configuration, the pulses are expected to be a factor tree shorter (3*64 cathodes), leading to a further increase in the photo response by a factor three.

The display device according to the invention may be arranged, for example, as a scanning device, for scanning a surface, such as bar-codes as will be described below, or fingerprints. In the latter case a high-resolution display is required. Here the emitting sub-pixels are arranged to illuminate a reflective object placed on an outer surface of the display or in the proximity of said display, and the light is reflected from said object and sensed by the sensing sub-pixels, as was described above. This invention provides for the implementation of line scans, by illuminating with one column, comprising several pixels, and measuring/sensing by another column such as a neighboring column. By shifting the emitting column, for example each blue-emitting column from left to right, while sensing by another, neighboring column, for example each green-emitting column, it is possible to scan over any surface. Especially, such a device may be used for scanning bar codes or the like when the device is in a scanning/sensing mode as indicated by FIG. 1b. Then information represented by said bar code may be displayed on the display surface when the device is in a light emitting mode, as in FIG. 1a. As described above, the illumination column may be a column emitting blue or green light, while the sensing column may be a column sensing green or red light.

A second application of the present invention is as an interactive display device. Here a separate light reflection device, such as a mirror pen, is arranged to be positioned in the proximity of the surface of said display, said display being a matrix display comprising a plurality of pixels, each comprising sub-pixels as described above. When said reflection device is placed close to the display surface, it reflects light emitted from said display, which the reflected light may be detected by the sensing sub-pixels of the display. A reflection device having a reflective surface smaller than the display area may be used as a pointer, i.e. as an alternative “mouse device” in order to generate an interactive display device.

It should be noted that a display utilizing the invention preferably comprises a plurality of pixels, each having two or more sub-pixels. In this case several surrounding pixels or sub-pixels may be used to detect light reflected from an object and emitted from a centrally positioned pixel or sub-pixel. Measurement information from several surrounding pixels/sub-pixels also makes it possible to acquire information regarding the shape of an object acting as a reflection surface. The spatial resolution of the scanning device may be improved thereby, compared with the use of only one sensing pixel or sub-pixel. Moreover, a display device in accordance with the invention may also be used, for example, for optical data-transfer applications. In this case two RGB polymer LED devices, essentially as described above, are used. High-energy pixels of a first device are arranged to transmit a signal containing information, for example, digital information, while the lower-energy pixels of a second device are arranged to receive and sense the signal and translate it into direct information. In summary, this invention provides for a interactive/scanning display device by spectrally subdividing the sensor stage and the emission stage of the display. The display is sensitive to light emitted by the display itself. Moreover, the emission and sensing of light occurs essentially simultaneously in a sensing state. The device is switchable between a light-emitting state and a scanning state. A reflecting object placed on or near the display surface is illuminated by (high-energy) emitting sub-pixels, while the reflected light is sensed under short-circuit conditions by (low-energy) sensing sub-pixels. The reflecting object may be a small mirror, for example placed on the tip of a mirror pen, or may be any alternative object, provided a certain amount of light (such as more than about 1% for MUX64 driving) of the incident light is reflected by the object and subsequently hits the active layer of a sensing sub-pixel. In the case of a mirror pen, an optimization due to geometry (since sensing and emitting are spatially separated) may be achieved. Furthermore, the display device has a low power consumption in the sensing state. Moreover, the leakage currents of the organic device are equal to zero. Therefore, their typical unstable behavior does not interfere with the sensing properties of the device. It should also be noted that, due to the size of the photo-response, a pulsed driving schedule is preferred or necessary for a proper functioning of such a display. It may be possible to improve the sensing amplitude further by decreasing the pulse time.

It should be noted that many variations and modifications of this invention are possible to those skilled in the art. For example, the method and device according to the invention may be applied to a single-segment device (lighting device), a segmented device, or a matrix display. The invention may also be used in passive as well as active matrix configurations. It should also be noted that zero voltage and zero current in this application are to be interpreted as essentially zero values. It should also be noted that essentially any technology may be used for generating the light to be reflected, as long as the dual-function (light emitting/sensing) sub-pixels is in accordance with the invention as described above. For most practical applications, however, it is not desired to use two technologies in the same display, and consequently, a preferred embodiment of this invention has sub-pixels all comprising an organic light emitting layer as described above, said sub-pixels being arranged to emit light of different wavelengths.

Moreover, it should be noted that two different scanning modes may be achieved by the present invention. In the first one, the scanning display is arranged to display a picture, and the display continues to display said picture in the sensing state. This is, for example, the case in the mirror pen example given above. This application requires a pulsed driving mode in order to be able to use sensing pixels simultaneously with emission pixels. The second scanning mode is a pure scanning mode, in which the emission is used to illuminate an object, while the sensing pixels are arranged to be operated simultaneously with the emission pixels.

1. A display device (5) comprising at least a first and a second sub-pixel (5a, 5b), said first sub-pixel (5a) being arranged to emit light of a first wavelength (λ1) and said second sub-pixel (5b) being arranged to emit light of a second wavelength (λ2), said first sub-pixel (5a) comprising a first light-emitting organic electroluminescent layer (1a), which is sandwiched between a first front electrode (2a) and a first back electrode (3a), wherein said first electrodes (2a, 3a) in a first state are arranged to apply an emission driving signal (Vₐₗ) across said first electroluminescent layer (1a) for generating an emission state in which light of said first wavelength (λ1) is emitted, and in a second state are arranged to apply a sensing driving signal (Vₐₛ) across said first electroluminescent layer (1a) in which light of said second wavelength (λ2) incident on said first sub-pixel (5a) may be detected.

2. A display device as claimed in claim 1, wherein said first electrodes (2a, 3a) are held at essentially the same potential, i.e. said sensing driving signal is a voltage having a value of essentially 0 volts.

3. A display device as claimed in claim 1, wherein light emitted from said second sub-pixel (5b) having said second wavelength (λ2) is arranged to be reflected and detected by said first sub-pixel (5a) in said light-sensing state.

4. A display device as claimed in claim 1, or 3, wherein light (λ1) emitted from said first sub-pixel (5a) has a lower energy content than light (λ2) emitted from said second sub-pixel (5b).

5. A display device as claimed in claim 1, comprising a plurality of pixels, each comprising a first and a second sub-pixel (5a, 5b), wherein light emitted from a chosen second sub-pixel is arranged to be reflected by an external reflection device, arranged in proximity of said display device, and is sensed by at least one first sub-pixel (5a) within a neighboring area.

6. A display device as claimed in claim 1, wherein said display comprises a plurality of pixels, and wherein light emitted from a second sub-pixel is arranged to be detected by a plurality of neighboring pixels, each having a corresponding first sub-pixel.

7. A device as claimed in claim 1, wherein said first front and back electrodes (2a, 3a) each have a work function (Φ₁,Φ₂), the difference between said work functions being greater than 1 eV, preferably lying within an interval of 2 to 3.5 eV.

8. A device as claimed in claim 1, wherein at least one of said emission driving signals in the first, emission state and said sensing driving signals in the second, sensing state is constituted by a pulsed driving signal, the duration of the pulses being within an interval of 0 to 20 ms.

9. A device as claimed in claim 8, wherein said sensing driving signal in said second state, is a pulsed driving signal comprising high-intensity pulses, for amplifying the sensing driving signal.
